(19) United States
(12) Patent Application Publication
(10) Pub. No.: US 2015/0040979 A1
(43) Pub. Date: Feb. 12, 2015

(54) Silicon Wafers with p-n Junctions by Epitaxial Deposition and Devices Fabricated Therefrom

(71) Applicant: Crystal Solar Incorporated, Santa Clara, CA (US)

(72) Inventors: Tirunelveli S. Ravi, Saratoga, CA (US); Ruiying Hao, San Jose, CA (US)

(21) Appl. No.: 14/458,227

(22) Filed: Aug. 12, 2014

Related U.S. Application Data
(60) Provisional application No. 61/865,100, filed on Aug. 12, 2013.
(60) Provisional application No. 61/922,469, filed on Dec. 31, 2013.

(51) Int. Cl. H01L 31/18; H01L 31/0224; C30B 29/68; C30B 25/02; C30B 29/06; H01L 31/068; H01L 31/0236

(52) U.S. Cl. CPC H01L 31/1804; H01L 31/068; H01L 31/022441; H01L 31/02363; H01L 31/0684; C30B 25/02; C30B 29/06; C30B 29/68; H01L 31/1892
USPC 136/256; 136/261; 438/57

(57) ABSTRACT

High efficiency silicon solar cells, including IBC cells, may be formed from lightly doped p-n sandwich structures fabricated in-situ by epitaxial growth. For example, the solar cell may comprise: an n-type silicon layer greater than or equal to 20 microns thick, with a dopant concentration between 1E15/cm³ and 5E16/cm³ and a bulk silicon carrier lifetime greater than 50 microseconds; a p-type silicon layer greater than 10 microns thick, with a dopant concentration between 1E16/cm³ and 5E18/cm³, and a bulk silicon carrier lifetime greater than 10 microseconds; wherein the n-type and p-type silicon layers were fabricated by epitaxial deposition, one after the other, on a reusable single crystal silicon substrate. The ideality factor of the silicon solar cell may be approximately 1.0. The epitaxial deposition may be in a reactor with low auto-doping and low oxygen incorporation.

### CROSS-REFERENCE TO RELATED APPLICATIONS

This application claims the benefit of U.S. Provisional Application No. 61/865,100 filed Aug. 12, 2013, and U.S. Provisional Application No. 61/922,469 filed Dec. 31, 2013, both incorporated herein by reference in their entirety.

### FIELD OF THE INVENTION

The present invention relates generally to solar cells, and more particularly to methods for epitaxially-depositing single crystal silicon wafers with p-n junctions and solar cells fabricated therefrom.

### BACKGROUND

Conventional high efficiency p-type or n-type mono-crystalline silicon solar cells are made with as-cut silicon wafers of a thickness variation of 140 microns to 180 microns. These wafers have typical resistivities from 0.5 ohm-cm to 5 ohm-cm. Typically after a saw damage etch, an alkaline texture etch is applied followed by a diffusion step, passivation and front side ARC followed by metallizations. To get efficiencies of greater than 20%, advances have been made in the passivation of the front and the rear side of the solar cell. For example, thermal oxide has been added as a step to passivate the surface of a phosphorous diffused emitter and aluminum oxide is being seriously considered for passivation of a boron doped emitter for an n-type cell. Passivating heavily doped surfaces (greater than 5E20/cm³) is challenging and even for advanced cell designs like a selective emitter where the field regions have lower doping (approximately 5E19/cm³) than the regions underneath the contact, the passivation has not been sufficient. Furthermore, besides passivation, the bulk material requirements are enhanced making the silicon wafer itself more expensive. A high efficiency (greater than 20%) n-type wafer requires a lifetime of at least 500 micro-seconds and a high efficiency p-type wafer requires greater than 100 micro-seconds for the thicknesses mentioned above. This increases the cost of the monocrystalline wafer by 25% to 50% when compared to multicrystalline wafers. Because of these reasons, high efficiency mono-crystalline silicon structures have not been widely adopted for solar cell manufacturing.

To reduce the doping concentration further in the field region, when compared with conventional high efficiency p-type or n-type mono-crystalline silicon solar cells, approaches that grow the emitter epitaxially have been shown to work. For example Evelyn Schmich demonstrated a 5E18/cm³ doped epitaxial emitter on a standard monocrystalline silicon wafer as well as a low cost metallurgical grade silicon substrate. This device structure showed better blue response than a conventional diffused emitter. The thicknesses of these lightly doped emitters were tailored to give the appropriate sheet resistance needed for collecting the carriers using a conventional metallization scheme. “Emitter epitaxy for crystalline silicon wafers and thin-films: Solar cells and economical aspects” Evelyn Schmich et al. 23^{rd} Proceedings of European Photovoltaic Solar Energy Conference, 1-5 Sep. 2008, Valencia, Spain, pp. 2031-2036. However, the cost of these devices is still too high and the efficiency is still too low and further improvements are required.

Furthermore, interdigitated back contact (IBC) solar cells have traditionally produced the highest efficiency for silicon solar devices. The current state of the art of a 24% efficiency solar cell manufactured by Sunpower Corp. is an IBC solar cell where all of the junctions and the contacts are in the back of the cell. “Generation III high efficiency lower cost technology: Transition to full scale manufacturing” David D. Smith et al., Sunpower Corporation, Photovoltaic Specialists Conference (PVSC), 2012 38^{th} IEEE, pp. 001594-001597. However, with high efficiencies these types of cells are very expensive to produce. The starting material is a very high lifetime n-type material where a series of local, physically separated, n-type and p-type diffusion processes are carried out and contacts are made to the diffused regions. The number of cell making steps needed to make a conventional IBC cell is typically two to three times the number needed for a standard front to back contact solar cell. Many of these steps are needed to isolate the n and the p regions from one another. Recently, attempts have been made to simplify the cell making process for an IBC cell by using alternate methods for doping such as implantation. “5.32 Wpeak cell power for large area industrial ion implanted IBC cells” PV Magazine, Aug. 15, 2013, available at http://www.pv-magazine.com/services/press-releases/details/beitrag/world-record--532-wpeak-cell-power-for-large-area-industrial-ion-implanted-ibc-cells_{—}100012409/#ixzz2nIXILeF3, last visited Dec. 29, 2013. However, implantation of boron and phosphorus require complex high temperature steps which might not be cost effective in manufacturing.

There is a need for more efficient manufacturing processes for thin silicon solar cells and for manufacture of the thin silicon wafers from which these cells are fabricated, and for improved thin silicon solar cell designs.

### SUMMARY OF THE INVENTION

According to embodiments, a high efficiency silicon solar cell may be formed from a lightly doped p-n sandwich structure which can be fabricated in-situ by epitaxial growth. According to embodiments, a silicon solar cell may comprise: an n-type silicon layer greater than 20 microns thick and in embodiments 20 microns to 100 microns thick, with a dopant concentration between 1E15/cm³ and 5E16/cm³ and a bulk silicon carrier lifetime greater than 50 microseconds; a p-type silicon layer greater than 10 microns thick, in embodiments greater than 20 microns thick, in further embodiments between 20 and 100 microns thick, and in yet further embodiments about 65 microns thick, with a dopant concentration between 1E16/cm³ and 5E18/cm³, and a bulk silicon carrier lifetime greater than 10 microseconds; wherein the n-type and p-type silicon layers were fabricated by epitaxially deposition, one after the other, on a reusable single crystal silicon substrate. Furthermore, the ideality factor of the silicon solar cell may be approximately 1.0. Furthermore, the epitaxial deposition may be in a reactor with very low levels of auto-doping, such as an epitaxial reactor as described in U.S. Patent Application Publication Nos. 2013/0032084, 2010/0215872 and 2010/0263587. Furthermore, the epitaxial deposition may be in a reactor with very low levels of oxygen incorporation, such that there is no appreciable Light Induced Degradation, such as an epitaxial reactor as described in U.S. Patent Application Publication Nos. 2013/0032084, 2010/0215872 and 2010/0263587.

According to embodiments, a high efficiency IBC cell may be formed from a lightly doped p-n sandwich structure which can be grown in-situ by epitaxial growth. According to embodiments, an IBC silicon solar cell may comprise: a 1E16/cm³ to 5E18/cm³ p-type silicon layer greater than 10 microns thick, in embodiments greater than 20 microns thick, in further embodiments between 20 and 100 microns thick, and a 1E15/cm³ to 5E16/cm³ n-type silicon layer greater than 70 microns thick, in embodiments between 80 and 170 microns thick, and in embodiments about 130 microns thick, formed by in-situ epitaxial deposition of the p-type layer followed by the n-type layer, with contacts to the n-type layer being formed in apertures etched through the p-type layer. Furthermore, a p+-type layer may be epitaxially grown first, followed by the p-type layer and then the n-type layer, where the p+-type layer may be used for making electrical contact to the p-type layer and also for contact passivation.

According to yet further embodiments, processes for fabricating the silicon solar cells of the present invention are described herein.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a cross-sectional view of a representation of a symmetric epitaxially-grown p-n junction silicon solar cell, according to some embodiments of the present invention;

FIG. 2 is a plot of Voc (mV) as a function of bulk lifetime for n-type and p-type silicon in a first example p-n solar cell such as shown in FIG. 1, according to some embodiments of the present invention;

FIG. 3 is a plot of efficiency (%) as a function of bulk lifetime for n-type and p-type silicon in a first example p-n solar cell such as shown in FIG. 1, according to some embodiments of the present invention;

FIG. 4 is a cross-sectional view of a representation of an IBC epitaxially-grown silicon solar cell, according to some embodiments of the present invention;

FIG. 5 is a plot of efficiency (%) as a function of bulk lifetime for n-type and p-type silicon in a p-n solar cell such as shown in FIG. 4, according to some embodiments of the present invention;

FIG. 6 is a plot of efficiency (%) as a function of bulk lifetime for n-type and p-type silicon in a second example p-n solar cell such as shown in FIG. 1, according to some embodiments of the present invention;

FIG. 7 is a graph of current density against voltage for a third example p-n solar cell such as shown in FIG. 1, according to some embodiments of the present invention; and

FIG. 8 is a graph of carrier concentration against depth determined by spreading resistance profiling for the third example p-n solar cell.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

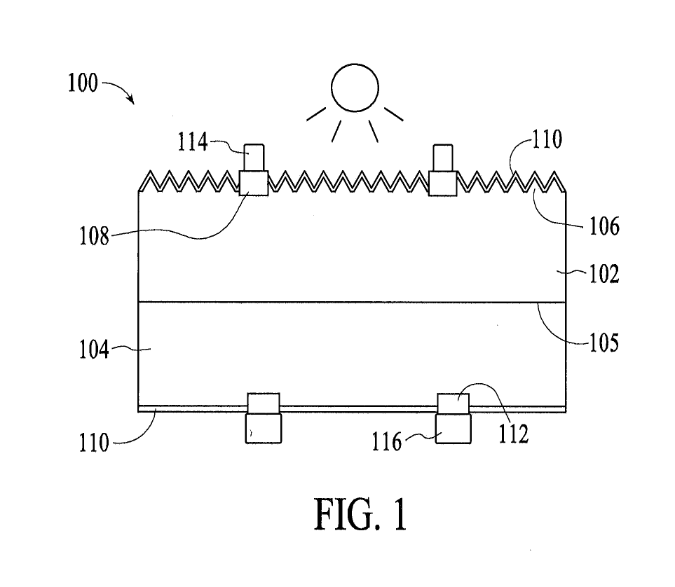

To overcome the manufacturing challenges with the prior art design of high efficiency n-type and p-type solar cells, it is proposed that a lightly doped p-n sandwich structure (easy to passivate front and back) is used; this structure is grown in-situ by epitaxial growth. An example of the proposed solar cell structure is shown in FIG. 1, where the thickness of the n-type silicon layer is about 65 microns and the thickness of the p-type silicon layer is also about 65 microns and is grown directly above the n-type layer in-situ in an epitaxial deposition chamber.

According to embodiments, a silicon solar cell may comprise: an n-type silicon layer 20 microns to 100 microns thick, with a dopant concentration between 1 E16/cm³ and 1E17/cm³ and a bulk silicon carrier lifetime greater than 50 microseconds; a p-type silicon layer 20 microns to 100 microns thick, with a dopant concentration between 1E16/cm³ and 1E17/cm³, and a bulk silicon carrier lifetime greater than 10 microseconds; wherein the n-type and p-type silicon layers are epitaxially deposited.

Crystal Solar's epitaxial reactor, as described in U.S. Patent Application Publication Nos. 2013/0032084, 2010/0215872 and 2010/0263587, all incorporated in their entirety by reference herein, provides a low cost, high throughput tool for epitaxial silicon deposition by chemical vapor deposition (CVD) which can be utilized for the above epitaxial deposition processes. Moreover, U.S. Patent Application Publication No. 2013/0032084 describes fabrication of silicon wafers by epitaxial growth—for some embodiments a thin silicon wafer is epitaxially grown with a built-in p-n junction as described herein.

The thicknesses of the p-type and n-type epitaxially deposited silicon layers are chosen to provide an effective sheet resistance of approximately 50 Ohms/sq., which is appropriate for current contact grid lines for solar cells, although thicknesses may be changed as needed to provide specific device properties, including sheet resistances.

An example of a process flow to make a solar cell 100 such as shown in FIG. 1 is provided below and it is expected that this process may be incorporated in a standard p-type silicon solar cell manufacturing line.

(1) a thin silicon wafer is epitaxially deposited on a reusable single crystal silicon substrate; the wafer may comprise a 1E16/cm³ to 1E17/cm³ p-type silicon layer 104 greater than 10 microns thick, in embodiments greater than 20 microns thick, in further embodiments between 20 and 100 microns thick, and in yet further embodiments about 65 microns thick, and having a bulk lifetime of greater than 10 microseconds, and a 1E16/cm³ to 1E17/cm³ n-type silicon layer 102 between 20 and 100 microns thick, and in embodiments about 65 microns thick, and having a bulk lifetime of greater than 50 microseconds, formed by in-situ epitaxial deposition of one layer followed by the other in an epitaxial reactor such as described above. When using an epitaxial reactor such as described in U.S. Patent Application Publication Nos. 2013/0032084, 2010/0215872 and 2010/0263587, a very sharp p-n junction 105 may be formed, where such a sharp junction may be characterized by an ideality factor of approximately 1.0 for the solar cell 100.

(2) the p-n wafer is separated from the reusable silicon substrate by a process such as described in U.S. Patent Application Publication Nos. 2013/020111, 2013/0032084, 2010/0215872 and 2010/0263587.

(3) the p-n wafer is texture etched on one surface (typically the surface facing sunlight) using an etch such as an alkaline wet chemical etch (solutions containing potassium hydroxide (KOH) and isopropyl alcohol (IPA), for example), forming a textured surface 106.

(4) both sides of the p-n wafer are then subjected to a wafer clean followed by screen printing phosphorus diffusion paste on the n-type surface and driving the dopant into the n-type layer (by thermal diffusion) to form ohmic metal contacts 108 and also for contact passivation.

(5) deposit passivation layers 110, such as Al₂O₃ and SiNₓ, on both sides of the p-n wafer.

(6) open up windows in the passivation layers on the p-type side of the wafer where the contacts to the p-type layer will be formed—this may be achieved using a laser.

(7) screen print Ag paste to form fingers and busbars 114 on the coated n-type surface, where the fingers and busbars are aligned to, and make electrical contact with, the n⁺ phosphorus-diffused regions 108.

(8) screen print Al paste, for forming aluminum fired-through contacts 112, and screen print Ag busbars 116 on the p-type side. In further embodiments, blanket aluminum may be sputtered on the p-type surface instead of forming busbars.

(9) co-fire contacts.

(10) measure solar cell device operational characteristics, and bin according to application requirements.

Furthermore, variations on the above process flow may include alternative materials and deposition methods for the front-side and back-side electrical contacts. For example, front and back contact grids may be formed by depositing metal paste and firing, the front and/or back contact grids may also be formed by other techniques including electroplating of metals and alloys, such as copper (using a suitable barrier metallurgy such as Ni followed by copper plate-up). Furthermore, the front and/or back surface of the p-n wafer can have an epitaxially grown n⁺-layer and/or p⁺-layer (n⁺-layer on surface of n-type layer; p⁺-layer on surface of p-type layer), which is/are selectively etched for making electrical contacts and for contact passivation.

The advantages of a solar cell with a structure and fabrication process such as described above with reference to FIGS. 1-3 may include one or more of the following:

(a) a wide process margin for carrier lifetime in the epitaxially-deposited silicon and a wide process margin for the thickness of the p-type and n-type silicon layers. For example: to make good electrical contact to the solar cell device, all that is required is to be below a predefined maximum sheet resistance; efficiencies of up to 23% may be achieved with known techniques for passivation, such as described herein; and boron diffusion may not be needed.

(b) may be very easy to passivate using standard techniques; the low dopant concentration at n-type and p-type surfaces results in surface recombination velocities (SRVs) of less than 50 cm/sec, which have already been demonstrated.

(c) wide process margin on contact formation; for example, there is very little chance of shunting n-type and p-type regions, since the n-type and p-type regions are sufficiently thick—for example, in embodiments greater than 20 microns.

(d) relatively low requirements on the bulk silicon carrier lifetime due to the small (for example, less than 100 microns) thickness of the n-type and the p-type layers; it is calculated that carrier lifetimes of 100 μs for n-type silicon and 30 μs for p-type can yield greater than 20% efficiency solar cells and Crystal Solar has already demonstrated greater than 50 μs lifetime for p-type and greater than 200 μs for n-type epitaxially-deposited silicon.

(e) solar cells as described above can be perfectly bi-facial (the cell can be flipped and will provide substantially the same efficiency) or monofacial. Note that in embodiments the solar cell may by texture etched on both surfaces—front and back.

(f) epitaxially-deposited wafers as described above can be processed in a standard p-type solar cell line.

(g) no appreciable Light Induced Degradation (LID) due to the low oxygen level in the p-type epitaxially-deposited silicon (less than 1E18/cm³) and no LID for n-type epitaxially-deposited silicon.

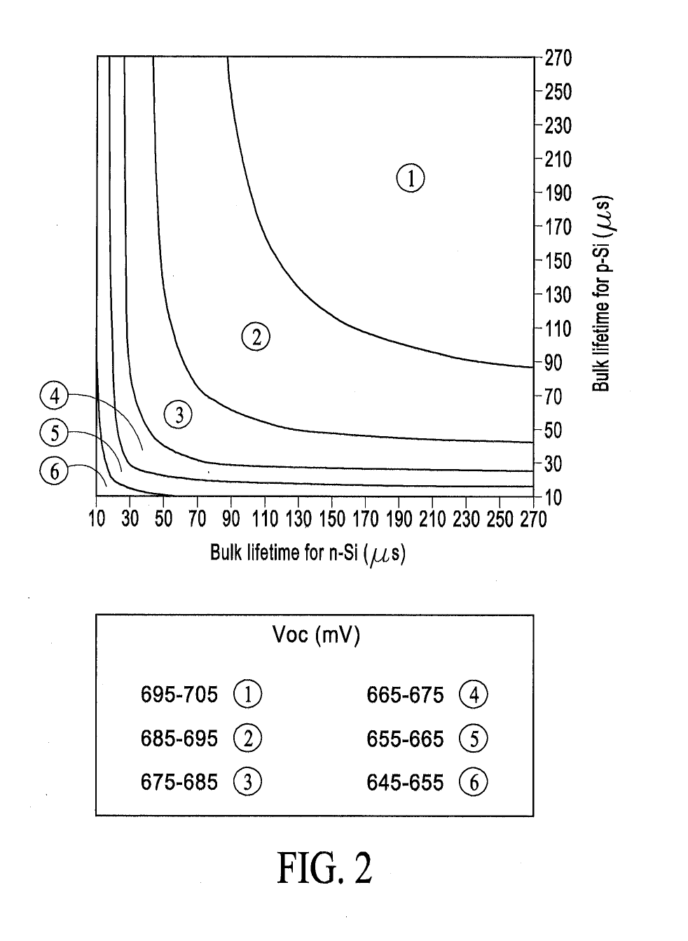

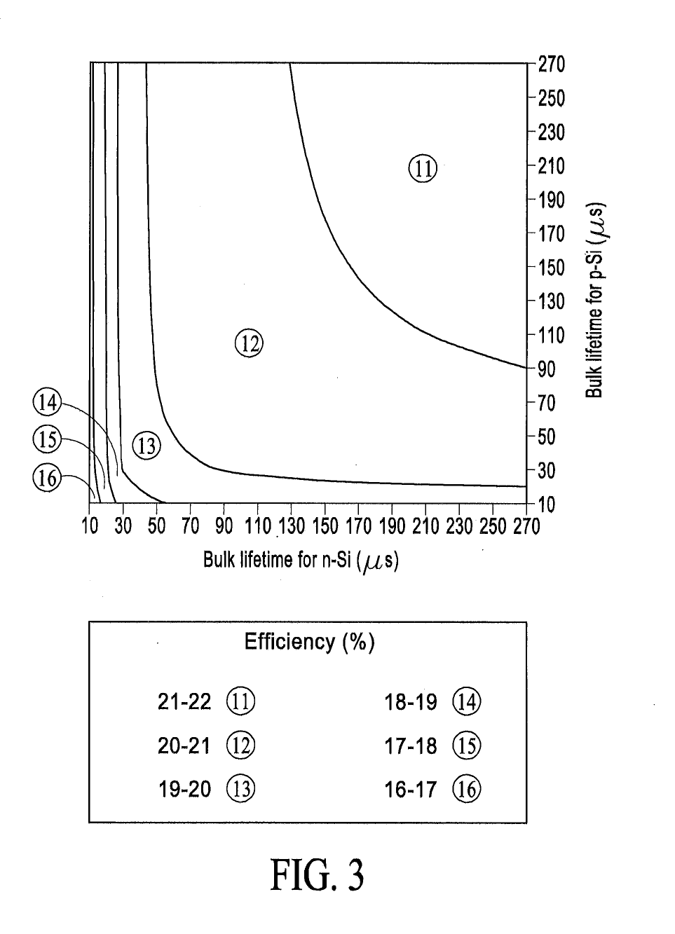

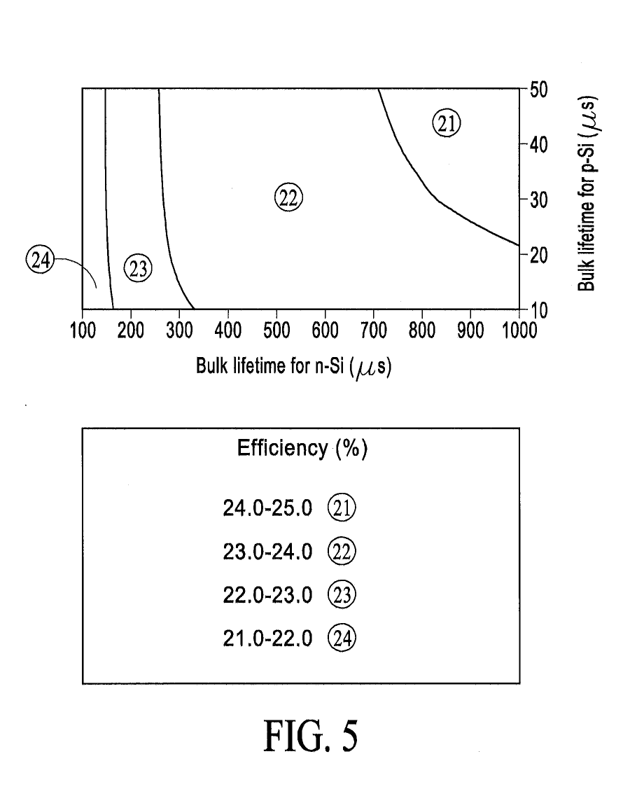

FIGS. 2 & 3 show calculated V_{oc} and efficiency, respectively as a function of bulk lifetime for n-type and p-type silicon in a p-n solar cell such as shown in FIG. 1 and described herein. FIG. 3 clearly shows a wide lifetime range for the n-type and p-type silicon parts of this solar cell structure for a high efficiency. Note that the simulated device characteristics shown in FIGS. 2 & 3 were generated using PC1D device modeling software. (This software was used to generate all of the simulations herein, including those in FIGS. 5 & 6.)

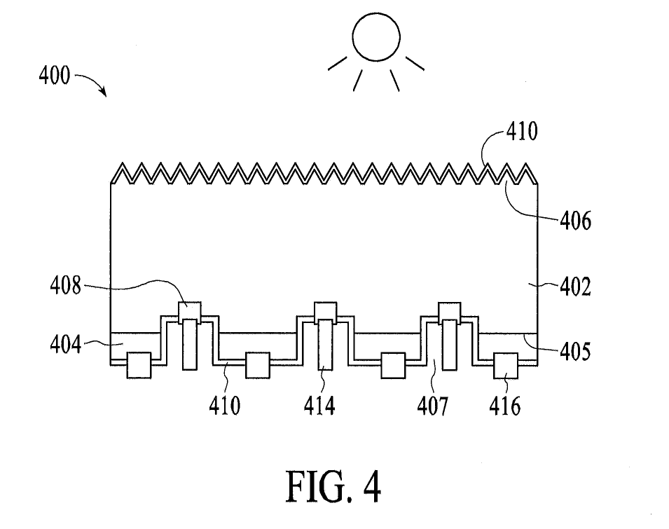

To overcome the manufacturing challenges with the prior art design of high efficiency IBC silicon solar cells, it is proposed that a lightly doped p-n sandwich structure is used; this structure is grown in-situ by epitaxial growth. An example proposed solar cell structure is shown in FIG. 4, where the thickness of the p-type layer 404 is about 20 microns and the thickness of the n-type layer 402 is about 130 microns and is grown directly above the p-type in-situ in an epitaxial deposition chamber.

According to further embodiments, a high efficiency IBC cell 400 may be formed from a lightly doped p-n sandwich structure which can be grown in-situ by epitaxial growth. These silicon wafers may comprise a 1E17/cm³ to 3E17/cm³ p-type silicon layer 404 about 20 microns thick and a 1E16/cm³ to 3E16/cm³ n-type silicon layer 402 about 130 microns thick, formed by in-situ epitaxial deposition of the p-type layer followed by the n-type layer, with contacts to the n-type layer being formed in apertures 407 etched through the p-type layer. Furthermore, a p⁺ type layer (not shown in the figure) may be epitaxially grown first, followed by the p-type layer and then the n-type layer, where the p⁺-type layer may be used for making electrical contact to the p-type layer and also for contact passivation.

Crystal Solar's epitaxial reactor, as described in U.S. Patent Application Publication Nos. 2013/0032084, 2010/0215872 and 2010/0263587, all incorporated in their entirety by reference herein, provides a low cost, high throughput tool for epitaxial silicon deposition by chemical vapor deposition (CVD) which can be utilized for the epitaxial deposition processes for the IBC cell. Moreover, U.S. Patent Application Publication No. 2013/0032084 describes fabrication of silicon wafers by epitaxial growth—for some embodiments of the present invention a thin silicon wafer is epitaxially grown with a built-in p-n junction as described herein.

The thicknesses of the p-type and n-type epitaxially deposited silicon layers are chosen to provide an effective sheet resistance of approximately less than 50 Ohms/square, which is appropriate for current contact grid lines for solar cells, although thicknesses may be changed as needed to provide specific device properties including sheet resistances and/or to improve the mechanical device yield.

An example of a process flow to make an IBC solar cell 400 such as shown in FIG. 4 is provided below and it is expected that this process may be incorporated in a standard p-type silicon solar cell manufacturing line.

(1) a thin silicon wafer is epitaxially deposited on a reusable single crystal silicon substrate; the wafer may comprise a 1E17/cm³ to 3E17/cm³ p-type silicon layer 404 greater than 10 microns thick, in embodiments greater than 20 microns thick, in further embodiments between 20 and 100 microns thick, and in yet further embodiments about 20 microns thick and a 1E16/cm³ to 3E16/cm³ n-type silicon layer 402 between 80 and 170 microns thick, and in embodiments about 130 microns thick, formed by in-situ epitaxial deposition of one layer followed by the other in an epitaxial reactor such as described above. When using an epitaxial reactor such as described in U.S. Patent Application Publication Nos. 2013/0032084, 2010/0215872 and 2010/0263587, a very sharp p-n junction 405 may be formed, where such a sharp junction may be characterized by an ideality factor of approximately 1.0 for the solar cell 400. Furthermore, a p+-type layer (not shown in figure) may be epitaxially grown first, followed by the p-type layer and then the n-type layer, where the p+-type layer may be used for making electrical contact to the p-type layer and also for contact passivation.

(2) the p-n wafer is separated from the reusable silicon substrate by a process such as described in U.S. Patent Application Publication Nos. 2013/020111, 2013/0032084, 2010/0215872 and 2010/0263587.

(3) the p-n wafer is texture etched on the front surface only (the front surface is the surface facing the sunlight) using an etch such as an alkaline wet chemical etch (solutions containing potassium hydroxide (KOH) and isopropyl alcohol (IPA), for example), forming a textured surface 406.

(4) 150 micron wide (finger regions) and 2 mm wide (busbar regions) channels 407 are laser scribed on the back of the p-n wafer (the contact side, the p-type side in this case) where the depth of the scribed regions is greater than the thickness of the p-type layer; the channels may also be formed by other processes such as reactive ion etching with a mask to define the channels.

(5) an etch may be used to remove laser-induced damage of the p-n wafer. Furthermore, the optional p⁺-type layer can also be selectively etched using an etch mask (such as a printed paste, or similar), where the remaining areas of the p⁺-type layers will be used for making ohmic contact to the p-type layer and also for contact passivation.

(6) screen print phosphorus diffusion paste in the middle of the n-channels and drive the dopant into the n-type layer (by thermal diffusion) to form ohmic metal contacts 408 and also for contact passivation.

(7) deposit passivation layers 410, such as Al₂O₃ and SiNₓ, on both sides of the p-n wafer.

(8) open up windows in the passivation layers on the back side of the wafer where the contacts to the p-type layer will be formed—this may be achieved using a laser.

(9) screen print Ag paste to form fingers and busbars 414 in the n-channels, where the fingers and busbars are aligned to, and make contact with, the n⁺ phosphorus-diffused regions 408.

(10) screen print Al paste and Ag busbars 416 on p-channels.

(11) co-fire contacts.

(12) measure solar cell device characteristics, and bin according to application requirements.

Furthermore, variations on the above process flow may include alternative materials and deposition methods for the electrical contacts. For example, contact grids may be formed by depositing metal paste and firing, or by other techniques including electroplating of metals and alloys, such as copper (using a suitable barrier metallurgy such as Ni followed by copper plate-up). Furthermore, contacts in the n-channels to the n-type layer may be formed by ion implantation, followed by thermal oxide growth on both sides of the p-n device to remove ion implantation damage, and also for passivation.

The advantages of a solar cell with a structure and fabrication process such as described above with reference to FIGS. 4 & 5 may include one or more of the following:

(a) a wide process margin for carrier lifetime in the epitaxially deposited silicon and a wide process margin for the thickness of the p-type and n-type silicon layers. For example: to make good electrical contact to the solar cell device, all that is required is to be below a predefined maximum sheet resistance; efficiencies of up to, and even greater than, 23% may be achieved with known techniques for passivation, such as described herein; and the devices may have high V_{oc} with good temperature coefficients—for example, a V_{oc} higher than 720 mV may be achieved, and the high V_{oc} from the lightly doped p-n sandwich structure may result in a more desirable temperature coefficient (TC) than that which has been reported in the literature for conventional diffused solar cells which have a TC of approximately −0.45%/° C.

(b) may be very easy to passivate using standard techniques; the low dopant concentration at n-type and p-type surfaces results in surface recombination velocities (SRVs) of less than 50 cm/sec, which have already been demonstrated.

(c) relatively low requirements on the bulk silicon carrier lifetime due to the small (for example, less than 100 microns) thickness of the n and the p layers.

(d) epitaxially-deposited wafers as described above can be processed in a standard p-type silicon solar cell line.

(e) no appreciable Light Induced Degradation (LID) due to the low oxygen level in the p-type epitaxially-deposited silicon (less than 1E18/cm³) and no LID for n-type epitaxially-deposited silicon.

(f) no POCl₃ (phosphorus doping) or BBr₃ (boron doping) diffusion processes are needed.

FIG. 5 shows calculated efficiency as a function of bulk lifetime for n-type and p-type silicon in a p-n solar cell such as shown in FIG. 4 and described herein. FIG. 5 clearly shows a wide lifetime range for the n-type and p-type silicon parts of this solar cell structure for a high efficiency, and shows that very high efficiencies (greater than 24%) are possible in a structure with relatively few process steps and with relatively easily obtainable bulk lifetimes (when compared with the prior art).

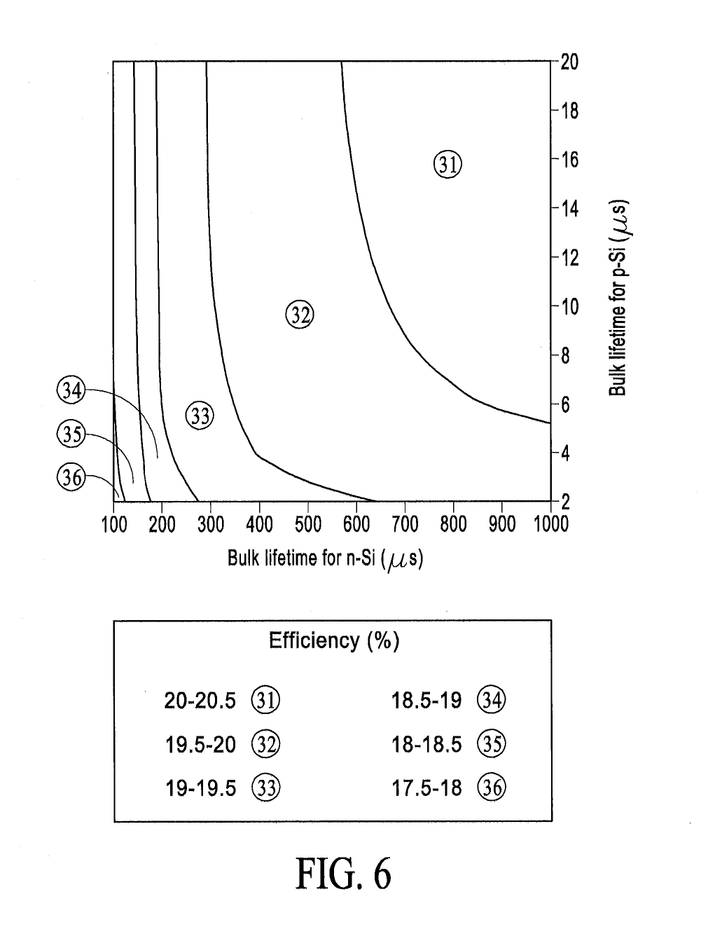

In a further embodiment based on the structure of FIG. 1, a solar cell may be fabricated with an n-type Si layer approximately 150 μm thick doped at between 4E15/cm³ and 5E15/cm³ with a bulk lifetime of greater than 500 microseconds and a p-type Si layer approximately 30 μm thick doped at approximately 1E17/cm³ with a bulk lifetime of greater than 10 microseconds. The device may be fabricated as described above with reference to FIG. 1, although the following variations in the process may be used. Contacts on the texture etched surface of the n-type layer may be formed by ion implantation, followed by thermal oxide growth on both sides of the p-n device to remove ion implantation damage, and also for passivation. FIG. 6 shows calculated efficiency as a function of bulk lifetime for n-type and p-type silicon in a p-n solar cell such as shown in FIG. 1 and fabricated as described immediately above. FIG. 6 clearly shows a wide lifetime range for the n-type and p-type silicon parts of this solar cell structure for a high efficiency.

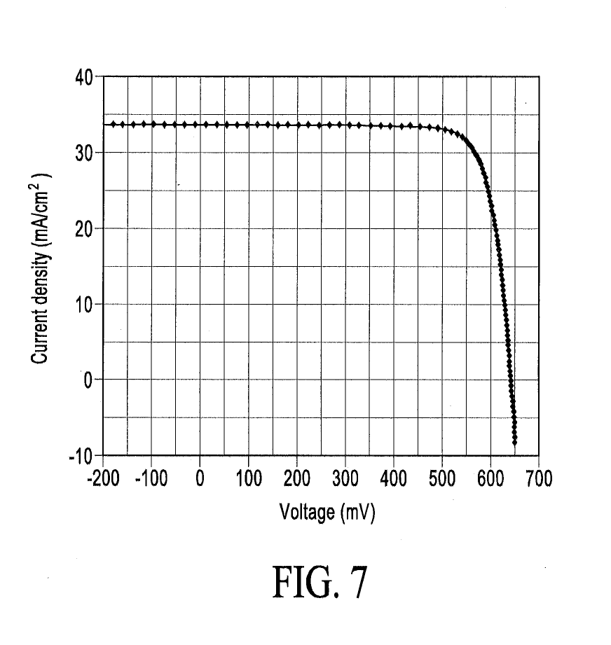

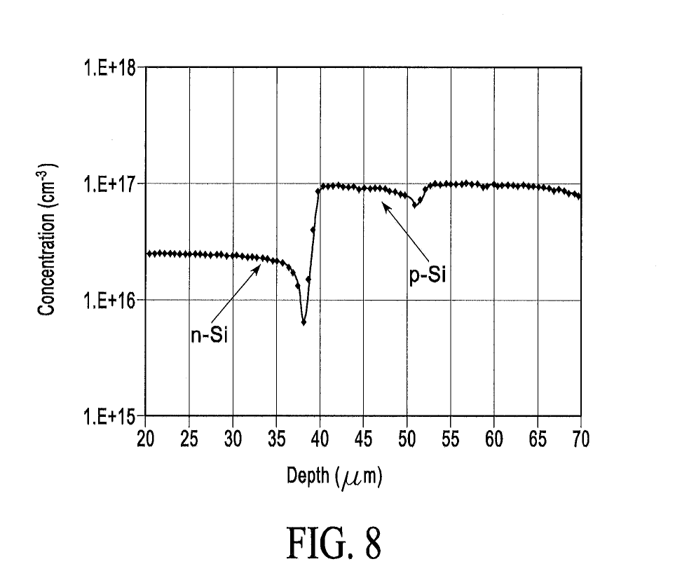

A solar cell as in FIG. 1 has been fabricated using the process flow as described herein with reference to FIG. 1, with an n-type Si layer approximately 50 μm thick doped at 3E16/cm³ and a p-type Si layer approximately 100 μm thick doped at approximately 1E17/cm³. FIG. 7 shows a graph of current density against voltage for this solar cell and FIG. 8 shows a graph of carrier concentration against depth determined by spreading resistance profiling for this solar cell. This device has been characterized as specified in Table 1. Note the ideality factor of 1.02 indicating a high quality pn junction, as described in more detail below.

TABLE 1

| | |
|---|---|
| Voc (mV) | 639.7 |
| Jsc (mA/cm²) | 33.7 |
| FF (%) | 80.4 |
| Efficiency (%) | 17.3 |
| Ideality Factor | 1.02 |
| Rs (Ohm-cm²) | 0.6 |
| Rsh (Ohm-cm²) | 8840 |

The ideality factor measures the junction quality and the recombination in a solar cell. An ideal pn-junction has an ideality factor near unity over a large bias range, where there is only recombination of the minority carriers due to band to band recombination or via traps in the quasi-neutral regions. The ideality factor has a higher value than unity when other (undesirable) recombination mechanisms occur. For example, recombination through two carriers in the depletion region leads to an ideality factor of 2. Local shunts at edges or underneath the emitter grid lines resulting from the prior art industrial solar cell fabrication process have been reported to show a high ideality factor. Epitaxial growth usually has defects including stacking faults, spikes, etc. Stacking faults have been assumed to be comparatively harmless, but spikes, for instance, have been reported to have a detrimental effect on the epitaxial layer and may lead to local shunting. See, for example, Shunt-analysis of epitaxial silicon thin-film solar cells by lock-in thermography, Bau, S. et al., Conference Record of the Twenty-Ninth IEEE Photovoltaic Specialists Conference, 19-24 May 2002, pages 1335-1338. These and other recombinations can produce ideality factors that deviate from the desirable value of unity.

The preliminary results from a silicon solar cell with the general device structure of FIG. 1 are shown in FIGS. 7 & 8—the results show that an ideality factor of unity can be achieved. The excellent ideality factor may be attributed to a high quality epitaxially grown p-n junction, grown using the Crystal Solar epitaxially reactor and methods as described in U.S. Patent Application Publication Nos. 2013/0032084, 2010/0215872 and 2010/0263587, for example. The ideality factor of unity also points to a very sharp p-n junction, which can be achieved in these Crystal Solar epitaxial systems due, among other factors, to the very low levels of auto-doping during epitaxial deposition. Moreover, the device structure provides effective separation of the metal contacted surfaces far away from the depletion region, which effectively eliminates shunting. These advantages all together contributed to the high p-n junction quality.

Furthermore, the ideality factors of interdigitated back contact silicon solar cells as described herein may also achieve values of approximately 1.0, for the same reasons as given above.

Furthermore, in the examples provided above the devices are formed by epitaxial growth on a p-type silicon substrate; however, the concepts and principles of the present invention may also be applied to devices formed by epitaxial growth on an n-type silicon substrate. Yet furthermore, devices may be based on epitaxially grown wafers with many doping variations, including: n/p, p/n, n⁺/n/p/p⁺, n⁺/n/p, n/p/p⁺, p⁺/p/n/n⁺, p⁺/p/n and p/n/n⁺ wafers, for example.

Although the present invention has been particularly described with reference to solar cells with layers with various different ranges of layer thicknesses and layer doping levels, further embodiments may have n-type layer doping levels in the range of 1E15/cm³ to 5E16/cm³, and p-type layer doping levels in the range of 1E16/cm³ to 5E18/cm³.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A silicon solar cell comprising:
a p-type silicon layer greater than 10 microns thick with a dopant concentration between 1E16/cm³ and 5E18/cm³, and a bulk silicon carrier lifetime greater than 10 microseconds; and
on said p-type silicon layer, forming a p-n junction, an n-type silicon layer greater than 20 microns thick, with a dopant concentration between 1E15/cm³ and 5E16/cm³ and a bulk silicon carrier lifetime greater than 50 microseconds;
wherein the ideality factor of said silicon solar cell is approximately 1.0.

2. The silicon solar cell structure as in claim 1, wherein said p-type silicon layer is greater than 20 microns thick.

3. The silicon solar cell structure as in claim 1, wherein said p-type silicon layer is between 20 and 100 microns thick.

4. The silicon solar cell as in claim 1, wherein the oxygen concentration in said p-type silicon layer is less than 1E18/cm³.

5. The silicon solar cell as in claim 1, wherein there is no substantial light induced degradation.

6. The silicon solar cell as in claim 1, wherein said solar cell is bifacial.

7. The silicon solar cell as in claim 1, wherein said solar cell has textured front and back surfaces.

8. The silicon solar cell as in claim 1, wherein said n-type silicon layer has a dopant concentration between 1E15/cm³ and 1E17/cm³ and a bulk silicon carrier lifetime greater than 50 microseconds, and wherein said p-type silicon layer has a dopant concentration between 1E16/cm³ and 1E17/cm³, and a bulk silicon carrier lifetime greater than 10 microseconds.

9. The silicon solar cell structure as in claim 1, wherein said n-type silicon layer is between 20 and 100 microns thick.

10. An interdigitated back contact silicon solar cell comprising:
a p-type silicon layer greater than 10 microns thick with a dopant concentration between 1E16/cm³ and 5E18/cm³; and
on said p-type silicon layer, forming a p-n junction, an n-type silicon layer greater than 70 microns thick, with a dopant concentration between 1E15/cm³ and 5E 16/cm³;
wherein said p-type layer has channels etched completely through the thickness of said p-type layer to expose said n-type layer, and wherein electrical contacts to said p-type layer and said n-type layer are formed on the same, back side, of said solar cell.

11. The interdigitated back contact silicon solar cell as in claim 10, wherein said p-type silicon layer has a dopant concentration between 1E17/cm³ and 3E17/cm³ and said n-type silicon layer has a dopant concentration between 1E16/cm³ and 3E 16/cm³.

12. The interdigitated back contact silicon solar cell as in claim 10, wherein the ideality factor of said interdigitated back contact silicon solar cell is approximately 1.0.

13. The interdigitated back contact silicon solar cell as in claim 10, wherein said p-type silicon layer is greater than 20 microns thick.

14. The interdigitated back contact silicon solar cell as in claim 10, wherein said p-type silicon layer is between 20 and 100 microns thick.

15. The interdigitated back contact silicon solar cell as in claim 10, wherein the oxygen concentration in said p-type silicon layer is less than 1E18/cm³.

16. The interdigitated back contact silicon solar cell as in claim 10, wherein there is no substantial light induced degradation.

17. A method of fabricating a silicon solar cell comprising:
epitaxially depositing on a reusable single crystal silicon wafer a p-type silicon layer greater than 10 microns thick with a dopant concentration between 1E16/cm³ and 5E18/cm³, and a bulk silicon carrier lifetime greater than 10 microseconds;
epitaxially depositing on said p-type silicon layer, forming a p-n wafer, an n-type silicon layer greater than 20 microns thick, with a dopant concentration between 1E15/cm³ and 5E16/cm³ and a bulk silicon carrier lifetime greater than 50 microseconds; and
separating said p-n wafer from said reusable single crystal silicon wafer.

18. The method as in claim 17, wherein said n-type silicon layer has a dopant concentration between 1E15/cm³ and 1E17/cm³ and a bulk silicon carrier lifetime greater than 50 microseconds, and wherein said p-type silicon layer has a dopant concentration between 1E16/cm³ and 1E17/cm³, and a bulk silicon carrier lifetime greater than 10 microseconds.

19. A method of fabricating interdigitated back contact silicon solar cell comprising:
epitaxially depositing on a reusable single crystal silicon wafer a p-type silicon layer greater than 10 microns thick with a dopant concentration between 1E16/cm³ and 5E18/cm³;
epitaxially depositing on said p-type silicon layer, forming a p-n wafer, an n-type silicon layer greater than 70 microns thick, with a dopant concentration between 1E15/cm³ and 5E16/cm³ and a bulk silicon carrier lifetime greater than 50 microseconds;
separating said p-n wafer from said reusable single crystal silicon wafer; and
etching n-channels through the thickness of said p-type silicon layer to expose said n-type silicon layer.

20. The method as in claim 19, wherein said p-type silicon layer has a dopant concentration between 1E17/cm³ and 3E17/cm³ and said n-type silicon layer has a dopant concentration between 1E16/cm³ and 3E16/cm³.
